(19) United States
(12) Patent Application Publication
(10) Pub. No.: US 2010/0295182 A1
(43) Pub. Date: Nov. 25, 2010

(54) SEMICONDUCTOR DEVICE AND METHOD FOR MANUFACTURING THE SAME

(75) Inventors: Shuji HIRAO, Hyogo (JP); Syutetsu Kaneyama, Osaka (JP)

Correspondence Address: McDERMOTT WILL & EMERY LLP, 600 13th Street, N.W., Washington, DC, 20005-3096, US

(73) Assignee: PANASONIC CORPORATION, Osaka (JP)

(21) Appl. No.: 12/848,719

(22) Filed: Aug. 2, 2010

Related U.S. Application Data
(63) Continuation of application No. PCT/JP2009/000551, filed on Feb. 12, 2009.

(30) Foreign Application Priority Data
Feb. 15, 2008 (JP) 2008-034185

(51) Int. Cl. H01L 23/522; H01L 21/768

(52) U.S. Cl. 257/751; 438/653; 257/E23.142; 257/E21.584

(57) ABSTRACT

Provided is a method for forming a Cu wiring that does not cause Cu elution during CMP when a Ru material is used as a barrier metal film for the Cu wiring. The method has a step (d) of removing a second barrier metal film (Ru film) formed on a first barrier metal film on an upper surface of an interlayer insulating film, and a step (e) of depositing a seed copper (Cu) film on the first and the second barrier metal films after the step (d). By removing the second barrier metal film on the upper surface before the seed copper film is formed, copper is prevented from eluding into a slurry due to a battery effect of the second barrier metal film and copper.

### CROSS-REFERENCE TO RELATED APPLICATION

This is a continuation of International Application No. PCT/JP2009/000551 filed on Feb. 12, 2009, which claims priority to Japanese Patent Application No. 2008-034185 filed on Feb. 15, 2008. The disclosures of these applications including specifications, drawings and claims are incorporated herein by reference in their entireties.

### BACKGROUND OF THE INVENTION

1. Field of the Invention

The present invention relates to a semiconductor device having a highly reliable wiring and, specifically, relates to a micro-pattern filling in a technique for forming embedded wiring.

2. Description of the Related Art

Recently, copper (Cu) having a lower resistance than aluminum and a high electromigration (EM) immunity has attracted attention as a wiring material for realizing high integration and high speed operation of a semiconductor integrated circuit. Dry etching of Cu material is difficult, therefore a wiring manufacturing method wherein grooves and holes for wirings are formed in an insulating film beforehand, and then a barrier metal layer and a Cu seed layer are formed in order; then wirings are formed by embedding Cu using plating method, and subsequently the barrier metal layer is removed by chemical mechanical polishing (CMP) has been proposed.

Conventionally, a tantalum (Ta) thin film or the like formed by sputtering method was mainly used as a barrier metal for Cu. However, in a device with technology nodes of 32 nm or less, a wiring width is about 45 nm, sufficient coverage is not obtained by sputtering method, and a filling failure occurs during plating. Accordingly, a method of using ruthenium (Ru) or iridium (Ir) or the like that can be deposited by CVD (Chemical Vapor Deposition) method as a barrier metal has been proposed (see Japanese Laid-Open Patent Application Publication No. H10-229084).

Particularly, Ru material has satisfactory adhesion to Cu, as compared with Ta or its nitride (TaN) film or the like, an improvement on reliability can be expected. One example of a wiring manufacturing method using this material is described hereafter with reference to FIGS. 8A to 8C.

As shown in FIG. 8A, via holes 106 connected to a first Cu wiring 103 and wiring grooves 107 are formed in a second interlayer insulating film 104. A Ru film 105 being a barrier metal film is formed over an entire surface including an inside of the wiring grooves 107 and the via holes 106 by CVD method.

Next, a Cu film 108 is embedded in the wiring grooves 107 and the via holes 106 by CVD method (FIG. 8B).

Successively, Cu wirings and vias are formed by removing an excess portion of the Cu film 108 and Ru film 105 by means of chemical mechanical polishing (CMP) (FIG. 8C).

### SUMMARY OF THE INVENTION

However, the inventors made experiments on a Cu film for carrying out CMP with a Ru film as a barrier metal film, consequently they discovered such a phenomenon that the Cu film being a wiring material eluted due to a “battery effect” described later. The elution of the Cu film is a significant problem of deteriorating a yield and a reliability of a semiconductor device.

Here, a standard electrode potential of Cu (25° C., pH=0, referred to as E₀Cu) is 0.337 V, and the standard electrode potential of Ru (25° C., pH=0, referred to as E₀Ru) is 0.460 V. Electrochemical equilibrium equations of Cu and Ru are expressed by Eq. 1, Eq. 2 shown below.

Cu⁺+2e⁻=Cu 0.337 V vs. SHE (Eq. 1)

Ru⁺+2e⁻=Ru 0.460 V vs. SHE (Eq. 2)

Here, SHE (standard hydrogen electrode) means an electrode system in which a platinum wire is immersed in an aqueous solution of pH=0 and hydrogen of 1 atm is blown into it, and the electrode is used for a standard electrical potential when the reactions proceed.

Accordingly, “0.337 V vs. SHE” means that a reduction reaction of Cu starts at a potential of 0.337 V when the standard hydrogen electrode is 0 V. This electrical potential is called as the standard electrode potential. Generally, in a solution of containing a substance with a lower standard electrode potential and a substance with a higher standard electrode potential, the substance with the lower standard electrode potential tends to ionize. This is the “battery effect”.

Therefore, as shown in FIG. 9, in a case of performing Cu-CMP in a step shown in FIG. 8C, a reaction in which Cu emits an electron e⁻and is eluted as Cu⁺² in a solution proceeds, and a substance with a higher standard electrode potential (Ru) is precipitated out.

As shown in FIG. 10, in a case of performing barrier metal film-CMP after Cu-CMP in a step shown in FIG. 8C, a reaction in which Cu emits an electron e⁻and is eluted as Cu⁺² in a solution proceeds, and a substance with a high standard electrode potential (Ru) is precipitated out.

Here, the Cu-CMP means a polishing technique wherein copper is changed into weak copper oxide having a low mechanical strength with an electrolyte contained in a slurry solution (polishing agent) and then the copper oxide is polished by a mechanical pressure. The barrier metal film-CMP means a polishing technique wherein a barrier metal is changed into a weak oxide of a barrier metal film having a low mechanical strength with an electrolyte contained in a slurry solution (polishing agent) and then the oxide of the barrier metal film is polished by a mechanical pressure.

Hereafter, if Ru is used as the barrier metal film, the CMP method for removing the barrier metal film is expressed as Ru-CMP; if TaN is used as the barrier metal film, the CMP method for removing the barrier metal film is expressed as TaN-CMP. When a material other than the above materials is used as the barrier metal film, such notation is also the same.

The electrode potential of an actual CMP slurry solution is not consistent with a value of above standard electrode potential, however, if the electrode potential of the slurry is considered to keep the above relation (E₀Ru>E₀Cu) in view of an occurrence of Cu elution during CMP. It is perhaps possible that E₀Ru≅E₀Cu by devising the slurry solution, however, the composition of the slurry solution and so on are decided based on CMP properties in practice. Therefore, it is difficult to prevent the Cu elution by regulating the slurry solution.

In view of such a problem, an object in the present invention is to provide a method for forming a Cu wiring without occurrence of Cu elution during CMP when a Ru material is used as a barrier metal film for the Cu wiring.

The following means are adopted in the present invention to achieve the object.

First, a semiconductor device relating to the present invention comprises a wiring groove formed in an interlayer insulating film on a semiconductor substrate, a first barrier metal film formed on a side surface and a bottom surface of the wiring groove, and a second barrier metal film formed on the first barrier metal film at the side surface of the wiring groove. The semiconductor device also comprises a wiring with a film containing copper disposed in the wiring groove.

In the above semiconductor device, an upper end of the second barrier metal film on the side surface of the wiring groove has an inclined shape expanded upward. Or, the upper end of the second barrier metal film is lower than an upper end of the side surface of the wiring groove, and the film containing copper is in touch with the first barrier metal film on the upper end of the side surface of the wiring groove.

Next, a manufacturing method of a semiconductor device relating to the present invention comprises a step (a) of forming a wiring groove in an interlayer insulating film on a semiconductor substrate and a step (b) of depositing a first barrier metal film on a side surface and a bottom surface of the wiring groove as well as on an upper surface of the interlayer insulating film after the step (a). The manufacturing method also comprises a step (c) of depositing a second barrier metal film on the first barrier metal film after the step (b).

Then, the method comprises a step (d) of removing the second barrier metal film deposited on the first barrier metal film on the upper surface of the interlayer insulating film after the step (c), and a step (e) of depositing a seed film containing copper on the first and the second barrier metal films after the step (d). Thus, an elution of Cu into a slurry due to a battery effect between the second barrier metal film and copper can be prevented by removing the second barrier metal film on the upper surface before the seed film is formed.

Moreover, the manufacturing method of a semiconductor device relating to the present invention comprises a step (f) of depositing a plating film containing copper on the seed film after the step (e), and a step (g) of forming a copper wiring by removing the films containing copper and the first barrier metal film outside the wiring groove using chemical mechanical polishing after the step (f).

Here, in the step (d), the second barrier metal film may be removed so that an upper end of the second barrier metal film on the side surface of the wiring groove is lower than an upper end of the side surface of the wiring groove. Thereby, an elution of Cu in the wiring groove due to the battery effect can be prevented more reliably because the second barrier metal film is not exposed to a polished surface during CMP for the films containing copper.

Moreover, a standard electrode potential of the first barrier metal film is equal to or lower than that of copper, and a standard electrode potential of the second barrier metal film is higher than that of copper. Thereby, an elution of Cu due to the battery effect can also be prevented during CMP for the barrier metal films.

Furthermore, in the step (c), the second barrier metal film can also be formed discontinuously. Thereby, it is possible to provide an effect that a corrosion of copper is even harder to occur because a contact area between the second barrier metal film and slurry is small.

The second barrier metal film may be made of ruthenium (Ru) or an alloy containing ruthenium as a main component. The first barrier metal film may be a conducting film being tantalum, a conducting film being a compound of tantalum and at least one of nitrogen, carbon and silicon, or a laminated film of tantalum and the compound.

Then, the step (b) to the step (e) may be carried out in same equipment without being open to an atmosphere. This is also preferable because a surface oxidation of the formed films is prevented and an adhesion between the films is secured. Particularly, the step (d) may be an anisotropic etching.

As described above, in the present invention, CMP for a Cu film on a Ru barrier film can be performed without an elution of Cu into a slurry, so that a high yield and an improvement on reliability on a semiconductor device can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A to 1D are process drawings showing a manufacturing process of a semiconductor device in a first embodiment relating to the present invention.

FIGS. 2A to 2C are process drawings showing a manufacturing process of a semiconductor device in a first embodiment relating to the present invention.

FIGS. 3A to 3C are process drawings showing a manufacturing process of a semiconductor device in a second embodiment relating to the present invention.

FIGS. 4A to 4C are process drawings showing a manufacturing process of a semiconductor device in a second embodiment relating to the present invention.

FIGS. 5A to 5C are process drawings showing a manufacturing process of a semiconductor device in a second embodiment relating to the present invention.

FIGS. 6A to 6D are process drawings showing a manufacturing process of a semiconductor device in a third embodiment relating to the present invention.

FIGS. 7A and 7B are process drawings showing a manufacturing process of a semiconductor device in a third embodiment relating to the present invention.

FIGS. 8A to 8C are process drawings showing a manufacturing process of a conventional semiconductor device.

FIG. 9 is an illustration showing corrosion in Cu-CMP.

FIG. 10 is an illustration showing corrosion in Cu-CMP.

### DETAILED DESCRIPTION OF PREFERRED EMBODIMENTS

### (First Embodiment)

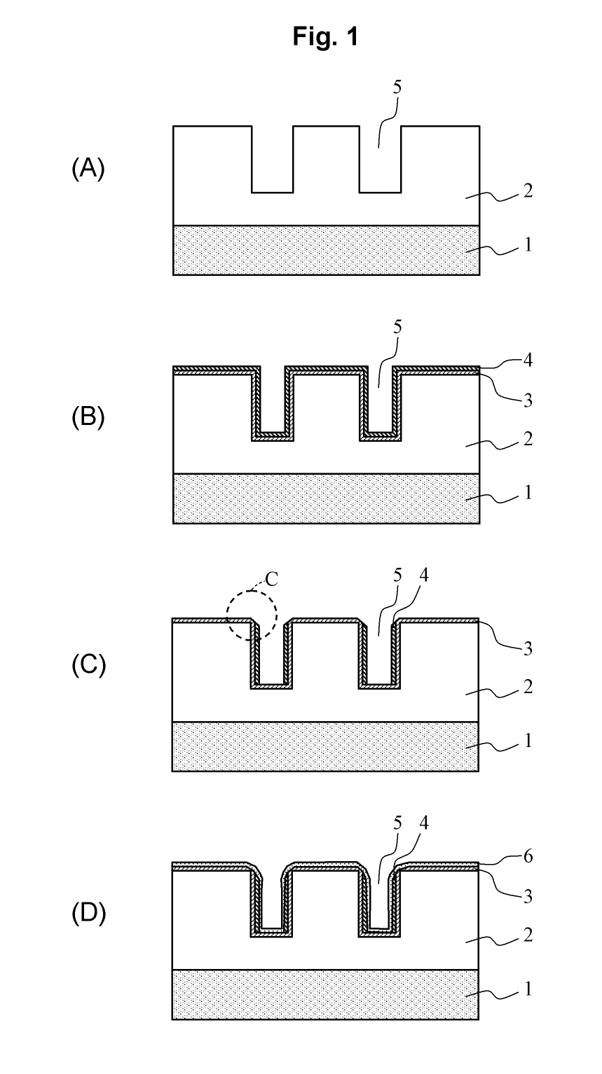

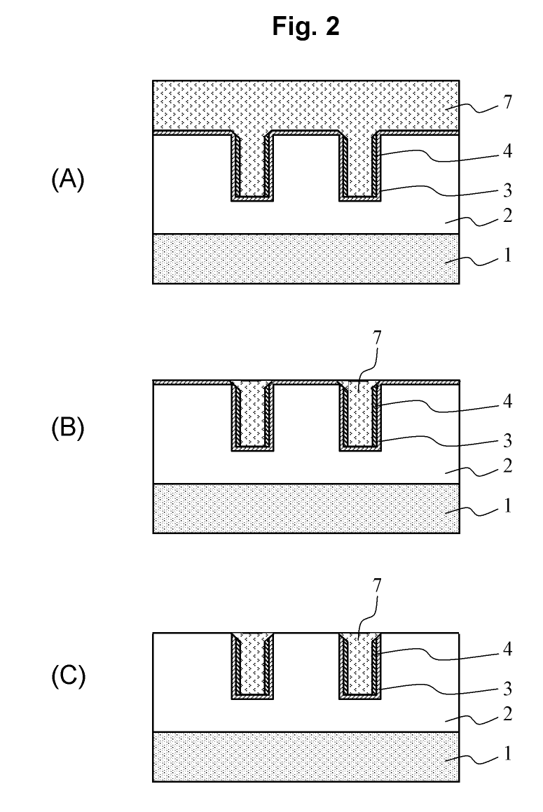

A manufacturing method in a first embodiment relating to the present invention is described by using FIGS. 1A to 1D and 2A to 2C.

First, as shown in FIG. 1A, a first interlayer insulating film 2 is formed on a semiconductor substrate 1 in a film thickness of 250 nm, and then a wiring groove 5 is formed in the first interlayer insulating film 2 by conventional lithographic technique and dry etching technique. The wiring groove 5 is connected to a semiconductor element, a capacitance element, a resistance element, and so on formed on the semiconductor substrate 1 to form an LSI (Large Scale Integrated Circuit) although they are omitted in the figure. A device of 32 nm node or finer is supposed, and a width of the wiring groove 5 is 50 nm or less. Here, an insulting film with a low dielectric constant, e.g., an SiOC film or a porous SiOC film having pores in the film or the like can be used as a material of the first interlayer insulating film 2.

Next, as shown in FIG. 1B, a first barrier metal film 3 and a second barrier metal film 4 are formed in order on the interlayer insulating film 2 including a side surface and a bottom surface of the wiring groove 5. Here, a tantalum nitride (TaN) film is used as the first barrier metal film 3. A ruthenium (Ru) film is used as the second barrier metal film 4. As methods for forming the barrier metal films, for instance, CVD (Chemical Vapor Deposition) method capable of forming a film with good coverage for a micro pattern can be used.

The TaN film 3 is formed by increasing a substrate temperature, e.g., within a range from 200° C. to 400° C. and repeating a step of introducing PDMAT (penta-dimethyl-amino-tantalum: structural formula Ta[N(CH₃)₂]₅) as a precursor into a chamber for a few seconds and successively a step of introducing ammonia (NH₃) gas as a reducing gas into the chamber for a few seconds. The film thickness of the TaN film 3 formed on the first interlayer insulating film 2 is within a range from 2 nm to 10 nm. It is also formed with good coverage, so that the film thickness is substantially equal even on the side surface and the bottom surface of the wiring groove.

The Ru film 4 is formed with good coverage due to thermal decomposition on the substrate by increasing the substrate temperature, e.g., within a range from 200° C. to 400° C. and introducing ruthenium carbonium [Ru(CO)₄]₃ into a chamber. The film thickness of the Ru film 4 formed on the TaN film 3 is within a range from 2 nm to 10 nm. It is also formed with good coverage, so that the film thickness is substantially equal even on the side surface and the bottom surface of the wiring groove.

The above first and second barrier metal films 3, 4 can also be formed by ALD (Atomic Layer Deposition) method instead of the above methods.

Next, as shown in FIG. 1C, the Ru film 4 formed on the TaN film 3 on the first interlayer insulating film 2 is removed by etch-back. For instance, a sputter etching with Ar ion (Ar etch-back) can be used as this removal method. In a case of Ar etch-back, an etching rate of the Ru film 4 is about a double as high as that of the TaN film, therefore only the Ru film at a top surface of the substrate can be removed in a remained state of the TaN film. Then, in an anisotropic etch-back such as Ar etch-back, because the etching rate is higher in an opening portion of the wiring groove 5 than that at the top surface, an upper end portion of the wiring groove 5 including the TaN film 3 and the Ru film 4 is formed into an inclined shape expanded upward (a position of a circle C in FIG. 1C).

Thus, the most significant feature of the present invention consists in that the Ru film 4 deposited on an upper surface of the TaN film 3 is removed before a plating copper film described later is formed.

Next, as shown in FIG. 1 D, a seed Cu film 6 acting as a seed layer during Cu electroplating is deposited on the TaN film 3 on the first interlayer insulating film 2, the side surface and the bottom surface of the wiring groove 5. For instance, a sputtering method is used for forming the seed Cu film 6. Particularly, an ionization sputtering method with a strong directivity may be used in a case of forming a micro pattern.

This seed Cu film 6 should be formed so as to be a continuous film on the side surface of the wiring groove 5 to fill the wiring groove 5 without forming voids in Cu electroplating. Particularly, Ru material has good wettability and adhesion to Cu, therefore a film continuity on the side surface of the wiring groove 5 can be secured even if the seed Cu film 6 is reduced its thickness (a thickness of film formed on Ru film 4: 3 nm or more), and then a satisfactory Cu electroplating can be carried out.

Here, the above term “wettability” is described briefly. A phenomenon in which Cu gathers together on a barrier metal film is called as “agglomeration”. Cu agglomerates on the barrier metal film that has been used so far, such as Ta and the like, when a heat treatment is carried out, so that a discontinuous Cu film is easily formed. However, when the barrier metal film is Ru, Cu does not agglomerate even if a heat treatment is carried out and can form a continuous Cu film. When the agglomeration does not occur like the latter, the wettability between Cu and the barrier metal film is said to be good.

It is also preferable that the semiconductor substrate 1 is conveyed in a same equipment in vacuum or in an inactive gas and continuously treated without being open to an atmosphere among treatments: deposition of the TaN film 3, deposition of the Ru film 4, Ar etch-back, and deposition of the seed Cu film 6 to prevent a surface oxidation of the films and secure an adhesion between each of the films.

In the step shown in FIG. 1B, if a total film thickness of the TaN film 3 and the Ru film 4 is obtained as a desirable film thickness, e.g., a thickness of 3 nm or more, in the wiring groove 5, these films 3, 4 may also be formed by ionization sputtering method. When the Ru film 4 is formed by ionization sputtering method, etch-back can also be continuously carried out by applying a bias to the substrate in a Ru sputtering chamber and by making an etching rate with Ar ion higher than the deposition rate. In this manner, a chamber for Ar etch-back is unnecessary, so that it is possible to realize a high-throughput treatment at a low cost.

Next, as shown in FIG. 2A, a plating Cu film is deposited on the TaN film 3 and the Ru film 4 including the inside of the wiring groove 5 by electroplating method, treated by annealing at a temperature within a range from 100° C. to 400° C., then the seed Cu film 6 and the plating Cu film are merged to form a Cu film 7.

Next, as shown in FIG. 2B, an excess portion of the Cu film 7 outside the wiring groove 5 is removed by CMP (Chemical Mechanical Polishing) method. At this time, the standard electrode potential of Cu (0.337 V vs. SHE) is lower than the standard electrode potential of Ru (0.460 V vs. SHE). However, as described above, the Ru film 4 deposited on an upper surface of the TaN film 3 has already been removed in the present invention. Therefore, an area of Ru exposed to a polished surface is very small (only a cross-section corresponding to a film thickness), so that a corrosion phenomenon in which Cu in the wiring groove 5 is eluted due to the battery effect does not occur in Cu-CMP.

Next, as shown in FIG. 2C, an excess portion of the TaN film 3 outside the wiring groove 5 is removed by barrier metal film-CMP. The standard electrode potential of the TaN film 3 is lower than the standard electrode potential of Cu, therefore a corrosion phenomenon in which Cu in the wiring groove 5 is eluted due to the battery effect does not occur in barrier metal film-CMP. As in Cu-CMP, the area of Ru exposed to the polished surface is very small, so that a corrosion phenomenon in which Cu in the wiring groove 5 does not occur in barrier metal film-CMP. Here, a little Cu film and Ru film existing outside the wiring groove 5 as residues are mechanically removed by polishing in barrier metal film-CMP.

As described above, in the manufacturing method of a semiconductor device in the first embodiment relating to the present invention, the second barrier metal film having the standard electrode potential higher than that of Cu is removed as shown in FIG. 1C. Therefore, the corrosion phenomenon in which Cu in the wiring groove 5 is eluted due to the battery effect does not occur in Cu-CMP and barrier metal film-CMP as shown in FIGS. 2B and 2C. As a result, this embodiment provides an effect that a semiconductor device having high yield and high reliability can be manufactured.

### (Second Embodiment)

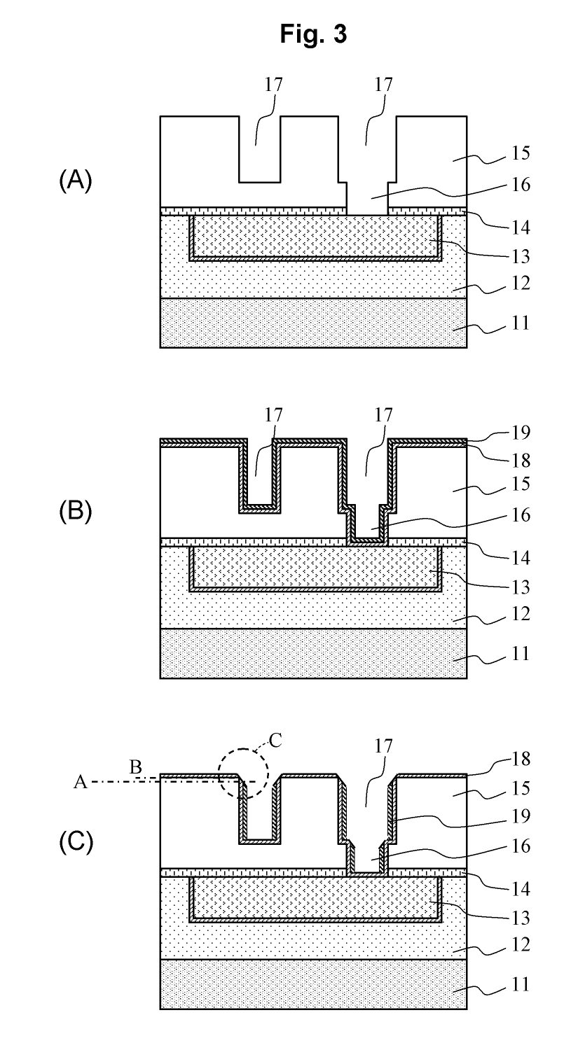

A manufacturing method of a semiconductor device in a second embodiment relating to the present invention is described with reference to FIGS. 3A to 3C, 4A to 4C, and 5A to 5C.

First, as shown in FIG. 3A, a first interlayer insulating film 12 is formed on a semiconductor substrate 11 in a film thickness of 250 nm, and then a first Cu wiring 13 is formed in the first interlayer insulating film 12. Then, a liner film 14 is formed on the first interlayer insulating film 12 and the first Cu wiring 13. Then, a second interlayer insulating film 15 is formed on the liner film 14. Subsequently, in the liner film 14 and the second interlayer insulating film 15, a via hole 16 reaching the first Cu wiring 13 and a wiring groove 17 for forming a second Cu wiring are formed. Here, an SiOC film or a porous SiOC film or the like can be used as materials for the first interlayer insulating film 12 and the second interlayer insulating film 15 as in the first embodiment.

Next, as shown in FIG. 3B, an upper surface of the first Cu wiring 13 exposed at a bottom of the via hole 16 is cleaned, and then a first barrier metal film 18 and a second barrier metal film 19 are formed in order on the second interlayer insulating film 15 including a side surface and a bottom surface of the wiring groove 17, and a side surface and a bottom surface of the via hole 16. Here, a tantalum nitride (TaN) film is used as the first barrier metal film 18. A ruthenium (Ru) film is used as the second barrier metal film 19. The cleaning of the upper surface of the first Cu wiring 13 at the bottom of via holes 16 is carried out by an annealing treatment at a temperature, e.g., within a range from about 250° C. to about 400° C., in hydrogen atmosphere or a plasma treatment with a gas containing argon (Ar) and hydrogen (H₂). The TaN film 18 and the Ru film 19 are formed by ALD method or CVD method as in the above first embodiment. If a total film thickness of the TaN film 18 and the Ru film 19 is obtained a desirable film thickness (e.g., 3 nm or more) on the side surface of the wiring groove 17 and the side surface of the via hole 16, these barrier metal films 18, 19 may also be formed by ionization sputtering method.

Next, as shown in FIG. 3C, the Ru film 19 formed on the TaN film 18 (top surface) on the second interlayer insulating film 15 is removed by anisotropic etching. For instance, Ar etch-back or the like is used as the anisotropic etching. In a case of Ar etch-back, like the first embodiment, an etching rate of the Ru film is about a double as high as that of the TaN film, therefore only the Ru film on the top surface can be removed in a remained state of the TaN film. Then, in the anisotropic etching such as Ar etch-back, because the etching rate is higher at an opening edge of the wiring groove 17 than that at the top surface, and an upper end portion of wiring groove 17 including the TaN film 18 and the Ru film 19 is formed into an inclined shape (a position of circle C in FIG. 3C).

In this embodiment, Ar etch-back is further carried out after the Ru film on the top surface of the second interlayer insulating film 15 is removed, and a height of an upper end surface of the Ru film (a dotted line A in FIG. 3C) is lower than a height of a position in touch with the second interlayer insulating film 15 and the first barrier metal film 18 (a dotted line B in FIG. 3C).

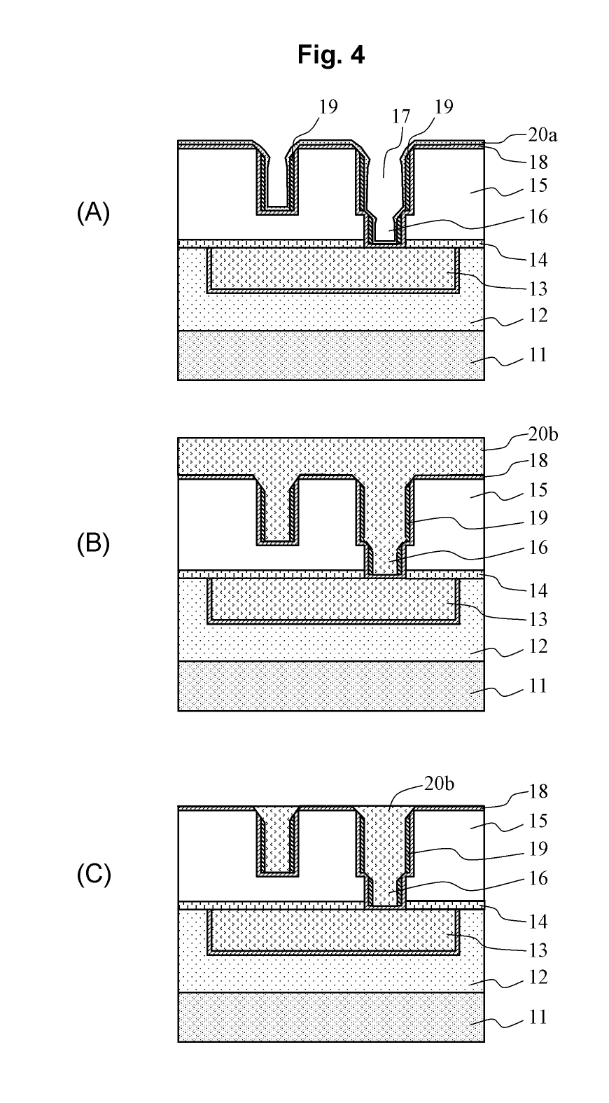

Next, as shown in FIG. 4A, a seed Cu layer 20a is deposited. The seed Cu layer 20a is deposited by ionization sputtering method and has a film thickness within a range from 10 nm to 40 nm. The Ru film 19 with good adhesion to Cu exists on the side surface of the wiring groove 17 and the via hole 16, so that the seed Cu layer 20a is not formed into a discontinuous film due to the above agglomeration. As a result, the seed Cu layer 20a can be a thin film. When the seed Cu layer 20a can be a thin film, a wide opening width of the wiring groove 17 and the via hole 16 after the deposition of the seed Cu layer 20a can be secured, therefore a filling process by Cu electroplating in the next step is made easy.

Next, as shown in FIG. 4B, a plating Cu film is deposited on the barrier metal film 18 including the inside of the wiring groove 17 and the via hole 16 by electroplating method, then the seed Cu layer 20a and the plating Cu film are merged to form a Cu film 20b by annealing at a temperature within a range from about 100° C. to about 400° C.

Next, as shown in FIG. 4C, an excess portion of the Cu film 20b outside the wiring groove 17 and the via hole 16 is removed by Cu-CMP. At this time, the standard electrode potential of Cu is lower than that of Ru, but the Ru film 19 does not expose to a polished surface, therefore a corrosion phenomenon in which Cu in the wiring groove 17 is eluted due to the battery effect does not occur in Cu-CMP.

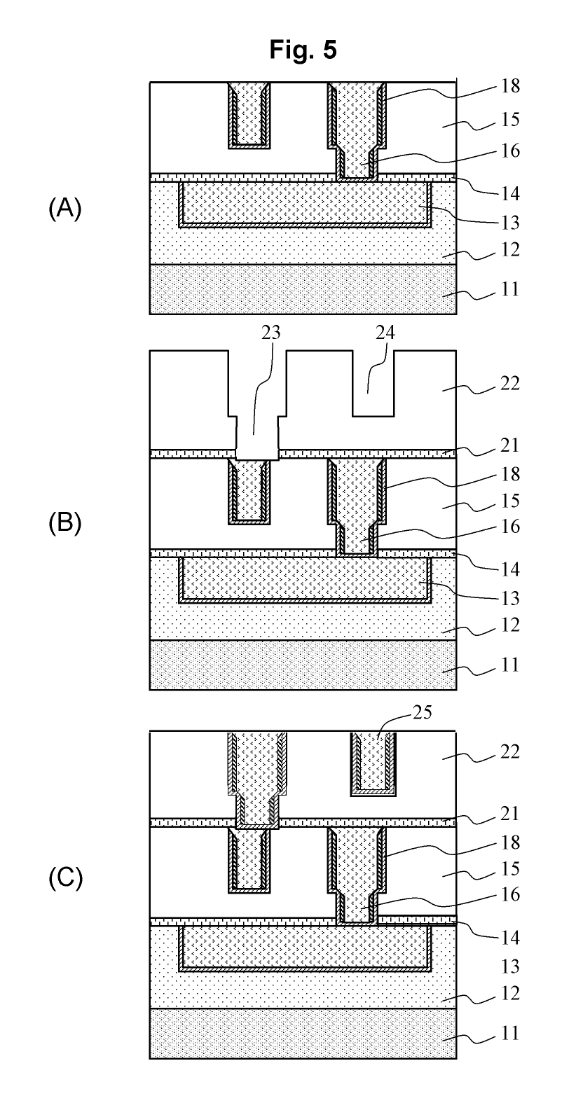

Next, as shown in FIG. 5A, an excess portion of TaN film outside the wiring groove 17 and the via hole 16 is removed by TaN-CMP. As in a case of Cu-CMP, the Ru film 19 is also not exposed to the polished surface in this case, therefore a corrosion phenomenon in which Cu in the wiring groove 17 is eluted due to the battery effect does not occur in TaN-CMP.

Next, as shown in FIG. 5B, a second liner film 21 and a third interlayer insulating film 22 are deposited in order on the second interlayer insulating film 15, then a second via hole 23 and a second wiring groove 24 are formed by conventional lithographic technique and dry etching technique. At this time, a cleaning treatment is performed in a state that the second liner film 21 is opened so as to expose the second Cu wiring, but the Ru film 19 is not exposed, therefore a corrosion phenomenon in which Cu in the wiring groove 17 is eluted due to the battery effect does not occur in this cleaning treatment.

When a similar cleaning treatment is carried out in the first embodiment, a contact area of a cleaning solution and the Ru film 4 is extremely small, so that the corrosion phenomenon in which Cu in wiring groove is eluted is hard to occur. Accordingly, there can be obtained a similar effect in a case of forming the via hole so as to connect to the wiring in the first embodiment.

Next, a third Cu wiring 25 is formed in the third interlayer insulating film 22 by the same step as the method described in FIGS. 3B to 5A. As a result, a structure shown in FIG. 5C is formed.

As described above, the Ru film 19 having the higher standard electrode potential than that of Cu is removed as shown in FIG. 3C in a manufacturing method of a semiconductor device in the second embodiment relating to the present invention. Further, the Ru film 19 is etched so that the height of the upper end surface of the Ru film 19 (A shown in FIG. 3A) to a position lower than the height of the position in touch with the second interlayer insulating film 15 and the TaN film 18 (B shown in FIG. 3C). As a result, the Ru film 19 is not exposed to the polished surface during Cu-CMP and barrier metal film-CMP as shown in FIGS. 4C and 5A. Therefore, the second embodiment provides an effect that a corrosion phenomenon in which Cu in the wiring groove 17 is eluted (the battery effect) does not reliably occur in Cu-CMP and barrier metal film-CMP compared with the manufacturing method of a semiconductor device in the first embodiment relating to the present invention.

In the first and second embodiments, it is described in a case of a pure Cu wiring, but the wiring may also be formed from a Cu alloy film. Although the embodiments refer to the use of the Ru film as the second barrier metal film, the present invention is also effective when metals having a higher standard electrode potential than that of Cu film (e.g., Rh, Pd, Ag, Os, Ir, Pt, Au) are used in place of the Ru film. Moreover, although the embodiments refer to the use of the TaN film as the first barrier metal film, any other materials usable as a barrier metal film may be used. As such materials, for instance, there are a Ta, a conducting film added with one or more of nitrogen, carbon, and silicon into Ta, a laminated film of Ta and a conducting film added with one or more of nitrogen, carbon, and silicon into Ta, or the like.

### (Third Embodiment)

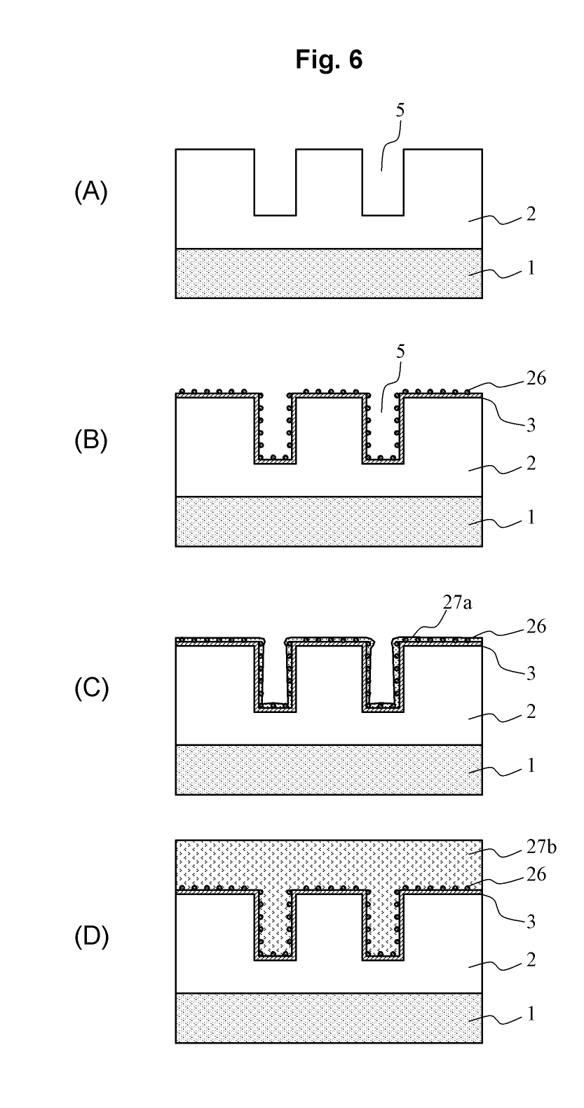

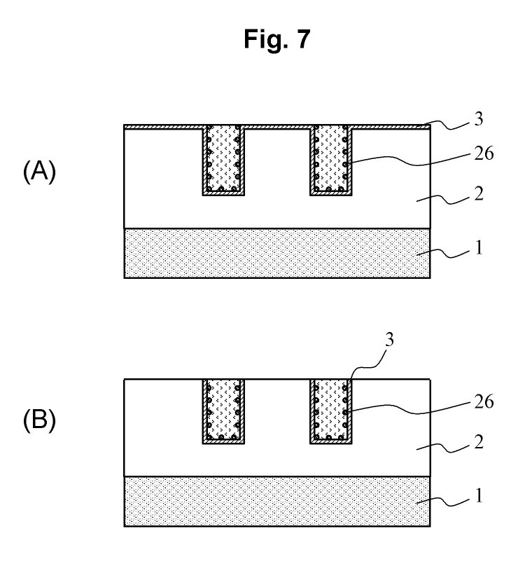

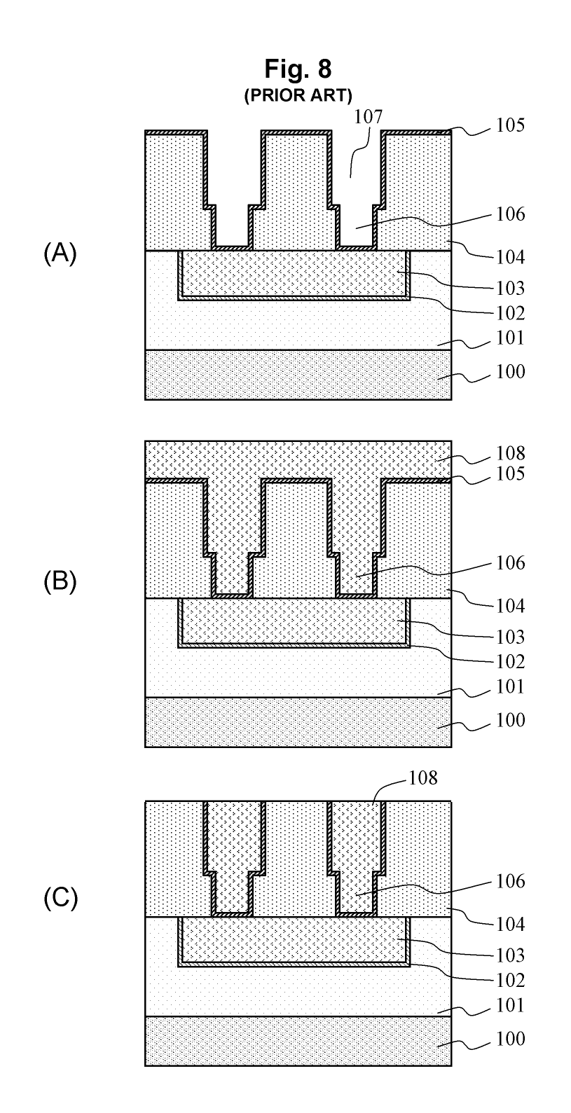

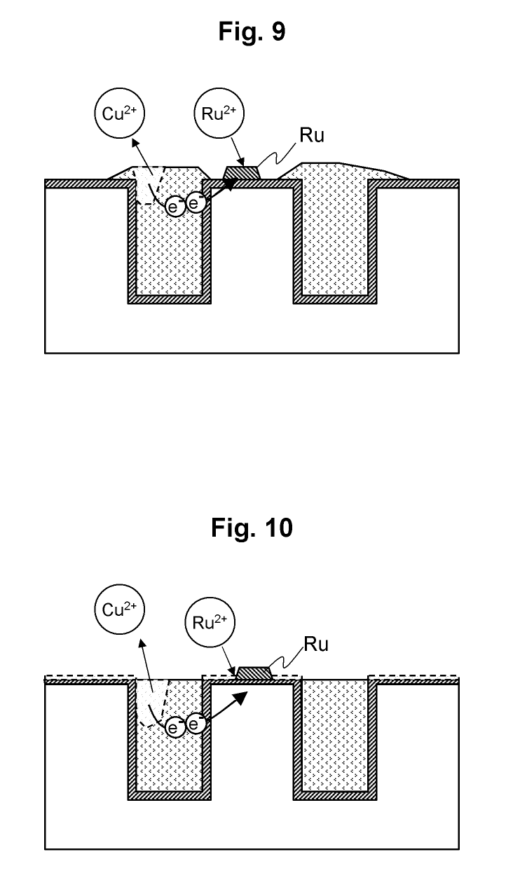

Although a case of forming the second barrier metal films 4, 19 so as to be continuous films in the first and second embodiments has been described, a case of forming these films 4, 19 so as to be discontinuous films will be described with reference to FIGS. 6A to 6D, 7A, and 7B. As a method of forming a discontinuous film, there is a method wherein a supply of a process gas is stopped before a forming film is to be a continuous film.

As shown in FIG. 6A, first, a first interlayer insulating film 2 is formed on a semiconductor substrate 1 in a film thickness of 250 nm, and then a wiring groove 5 is formed in the first interlayer insulating film 2. This is the same as the first embodiment.

Next, as shown in FIG. 6B, a first barrier metal (TaN) film 3 is formed on the first interlayer insulating film 2 including a side surface and a bottom surface of the wiring groove 5, and then a discontinuous film 26 which is a group of deposited Ru parts scattered on the TaN film 3 is formed by adjusting a supply of the process gas as described above.

Next, as shown in FIG. 6C, a seed Cu layer 27a is deposited on the Ru film 26 by ionization sputtering method. Then, as shown in FIG. 6D, a plating Cu film is deposited on the barrier metal film including an inside of the wiring groove 5 by electroplating method, then the seed Cu layer 27a and the plating Cu film are merged to form a Cu film 27b by annealing at a temperature within a range from about 100° C. to about 400° C. This is also same as the first embodiment.

Next, as shown in FIG. 7A, an excess portion of the Cu film 27b outside the wiring groove 5 is removed by Cu-CMP. At this time, each of Ru parts existing on a polished surface during Cu-CMP is discontinuous because of making the second barrier metal film 26 to be a discontinuous film, and then a contact area between the Ru parts and slurry is small, therefore this embodiment provides an effect that a corrosion does not occur in Cu-CMP.

Finally, as shown in FIG. 7B, an excess portion of the TaN film outside the wiring groove 5 is removed by TaN-CMP method. Almost no Ru exists on the polished surface during TaN-CMP, therefore this embodiment also provides an effect that a corrosion of Cu also does not occur in TaN-CMP.

As described above, in a manufacturing method of a semiconductor device, it is possible to realize high yield and high reliability. Accordingly, it is useful in formation of micro patterns of wirings in a semiconductor device.

What is claimed is:

1. A semiconductor device, comprising:
a wiring groove formed in an interlayer insulating film on a semiconductor substrate;
a first barrier metal film formed on a side surface and a bottom surface of the wiring groove;
a second barrier metal film formed on the first barrier metal film at the side surface of the wiring groove; and
a wiring with a film containing copper disposed in the wiring groove, and wherein
an upper end of the second barrier metal film on the side surface of the wiring groove has an inclined shape expanded upward.

2. A semiconductor device, comprising:
a wiring groove formed in an interlayer insulating film on a semiconductor substrate;
a first barrier metal film formed on a side surface and a bottom surface of the wiring groove;
a second barrier metal film formed on the first barrier metal film at the side surface of the wiring groove; and
a wiring with a film containing copper disposed in the wiring groove, and wherein
an upper end of the second barrier metal film is lower than an upper end of the side surface of the wiring groove, and the first barrier metal film and the film containing copper are in touch on the upper end of the side surface of the wiring groove.

3. A semiconductor device according to claim 1, wherein a standard electrode potential of the first barrier metal film is equal to or lower than that of copper and a standard electrode potential of the second barrier metal film is higher than that of copper.

4. A semiconductor device according to claim 2, wherein a standard electrode potential of the first barrier metal film is equal to or lower than that of copper and a standard electrode potential of the second barrier metal film is higher than that of copper.

5. A semiconductor device according to claim 1, wherein the second barrier metal film is discontinuously formed.

6. A semiconductor device according to claim 2, wherein the second barrier metal film is discontinuously formed.

7. A semiconductor device according to claim 1, wherein the second barrier metal film is made of ruthenium or an alloy containing ruthenium as a main component.

8. A semiconductor device according to claim 2, wherein the second barrier metal film is made of ruthenium or an alloy containing ruthenium as a main component.

9. A semiconductor device according to claim 1, wherein the first barrier metal film is a conducting film being tantalum, a conducting film being a compound of tantalum and at least one of nitrogen, carbon and silicon, or a laminated film of tantalum and the compound.

10. A semiconductor device according to claim 2, wherein the first barrier metal film is a conducting film being tantalum, a conducting film being a compound of tantalum and at least one of nitrogen, carbon and silicon, or a laminated film of tantalum and the compound.

11. A manufacturing method of a semiconductor device, comprising the steps of:
(a) forming a wiring groove in an interlayer insulating film on a semiconductor substrate;
(b) depositing a first barrier metal film on a side surface and a bottom surface of the wiring groove, and on an upper surface of the interlayer insulating film after the step (a);
(c) depositing a second barrier metal film on the first barrier metal film after the step (b);
(d) removing the second barrier metal film deposited on the first barrier metal film on the upper surface of the interlayer insulating film after the step (c);
(e) depositing a seed film containing copper on the first and the second barrier metal films after the step (d);
(f) depositing a plating film containing copper on the seed film after the step (e); and
(g) forming a copper wiring by removing the films containing copper and the first barrier metal film outside the wiring groove using chemical mechanical polishing after the step (f).

12. A manufacturing method of a semiconductor device according to claim 11, wherein, in the step (d), the second barrier metal film is removed so that an upper end of the second barrier metal film on the side surface of the wiring groove is lower than an upper end of the side surface of the wiring groove.

13. A manufacturing method of a semiconductor device according to claim 11, wherein a standard electrode potential of the first barrier metal film is equal to or lower than that of copper and a standard electrode potential of the second barrier metal film is higher than that of copper.

14. A manufacturing method of a semiconductor device according to claim 12, wherein a standard electrode potential of the first barrier metal film is equal to or lower than that of copper and a standard electrode potential of the second barrier metal film is higher than that of copper.

15. A manufacturing method of a semiconductor device according to claim 14, wherein, in the step (c), the second barrier metal film is discontinuously formed.

16. A manufacturing method of a semiconductor device according to claim 15, wherein the second barrier metal film is made of ruthenium or an alloy containing ruthenium as a main component.

17. A manufacturing method of a semiconductor device according to claim 16, wherein the first barrier metal film is a conducting film being tantalum, a conducting film being a compound of tantalum and at least one of nitrogen, carbon and silicon, or a laminated film of tantalum and the compound.

18. A manufacturing method of a semiconductor device according to claim 17, wherein the step (b) to the step (e) are carried out in same equipment without being opened to an atmosphere.

19. A manufacturing method of a semiconductor device according to claim 18, wherein the step (d) is an anisotropic etching.
